(19) United States
(12) Patent Application Publication
(10) Pub. No.: US 2026/0082932 A1
(43) Pub. Date: Mar. 19, 2026

(54) HIGH-INTEGRATED SUBSTRATE MANUFACTURING METHOD THEREFOR, AND POWER MODULE

(71) Applicant: MetaPWR Electronics Co., Ltd., Shanghai (CN)

(72) Inventors: Shouyu HONG, Shanghai (CN); Hongxiu LIU, Shanghai (CN); Qingdong CHEN, Shanghai (CN); Mingzhun ZHANG, Shanghai (CN)

(73) Assignee: MetaPWR Electronics Co., Ltd., Shanghai (CN)

(21) Appl. No.: 19/326,741

(22) Filed: Sep. 12, 2025

(30) Foreign Application Priority Data
Sep. 14, 2024 (CN) 202411289752.4

(51) Int. Cl. H01L 23/64; H01L 21/48; H01L 23/538; H01L 25/16

(52) U.S. Cl. CPC H10W 44/501; H10W 70/093; H10W 70/095; H10W 70/611; H10W 90/00; H10W 90/401

(57) ABSTRACT

The present invention is directed to a high-integrated substrate, which is laminated and stacked by means of a plurality of prefabricated boards. Electrical connections between prefabricated boards are realized by means of electrical connectors, thereby reducing solder joints and connective paths between layers; in addition, by disposing the element in the substrate, the space utilization rate of the substrate in the plane and the height direction is further improved; on the other hand, in the present invention, the part of the magnetic core is arranged in the accommodating space, and the accommodating space is in communication with the external space by means of the exhaust channel, so as to reduce the working temperature of the magnetic core assembly and improve the working performance of the magnetic core assembly, and at the same time, the reliability of the substrate in the service process is improved.

### CROSS-REFERENCE TO RELATED APPLICATIONS

This application claims the priority benefit of Chinese patent application serial no. 202411289752.4 filed on Sep. 14, 2024. The entirety of the above-mentioned patent application is hereby incorporated by reference herein and made a part of this specification.

### BACKGROUND

### Technical Field

The present invention relates to the technical field of substrate manufacturing, and particularly, to a high-integrated substrate manufacturing method therefor, and power module.

### Description of Related Art

In recent years, with the increasing demand of various types of artificial intelligence, data processing, etc. Global computing power consumption is experiencing explosive growth. Moreover, since the size limitation of these computing power units is extremely high, the requirements for the footprint, height, efficiency and heat dissipation of the energy processing unit are becoming higher and higher.

A typical two-stage power supply architecture, wherein the pre-stage converter is 48V to 12 V or 5V, and the post-stage converter is about 12V/5V to about 1 V of the working voltage of the processor. The pre-stage module usually comprises a magnetic element, that is, a transformer, since the voltage conversion thereof is relatively high; the post-stage usually uses a Buck circuit, and comprises a magnetic element, i.e. an inductor.

How to implement the integration of a magnetic element or the integration of a magnetic element and a power device, so as to reduce the area occupied by the module and improve the power density of the power conversion apparatus is a problem to be solved urgently at present. The traditional 3D stacked structure can easily reduce the reliability because the number of solder joints between the layers is large, which is another challenge to face. In addition, since the dynamic requirements of the load is higher and higher, a large number of capacitors need to be arranged adjacent to the load to improve dynamic performance, and therefore, how to set the output capacitor of the post-stage module to achieve the purpose of improving the dynamic performance of the load is an issue to be solved.

### SUMMARY

In view of the above, one of the objectives of the invention is to provide a high-integrated substrate, comprising a first prefabricated board, a second prefabricated board, a third prefabricated board, a first accommodating space and a second accommodating space, wherein the first prefabricated board, the second prefabricated board and the third prefabricated board are stacked in sequence; the first accommodating space is arranged between the first prefabricated board and the second prefabricated board, and the second accommodating space is arranged between the second prefabricated board and the third prefabricated board;

the second prefabricated board further comprises at least two opening windows, and the opening windows penetrate the upper surface and the lower surface of the second prefabricated board;

the high-integrated substrate further comprises a magnetic assembly, at least two conductive connectors, a bonding medium, and an exhaust channel;

the magnetic assembly comprises a winding and a magnetic core assembly; the winding is disposed in or on a surface of a second prefabricated board and is disposed adjacent to the opening window; the magnetic core assembly comprises an upper magnetic cover, a lower magnetic cover and a magnetic column, wherein each magnetic column passes through one of the opening window, and the upper magnetic cover and the lower magnetic cover respectively assembled with the board from the upper surface and the lower surface of the second prefabricated board; the upper magnetic cover is accommodated in the first accommodating space, and the lower magnetic cover is accommodated in the second accommodating space;

the first prefabricated board and the second prefabricated board, as well as the second prefabricated board and the third prefabricated board, are bonded and fixed by means of a bonding medium;

the at least two conductive connectors are electrically connected to two ends of the winding respectively, one of the conductive connectors is electrically connected to the first prefabricated board, and the other of the conductive connectors is electrically connected to the third prefabricated board;

the exhaust channel realizes communication between the first accommodating space and/or the second accommodating space and the outside.

Preferably, a length L of the winding is greater than a thickness H of the upper magnetic cover.

Preferably, a gap exists between an outer surface of the magnetic core assembly and an inner wall of the first accommodating space and the inner wall of the second accommodating space.

Preferably, the exhaust channel penetrates through an upper surface and a lower surface of the first prefabricated board; or the exhaust channel is disposed on a sidewall of the first prefabricated board, the second prefabricated board, or the third prefabricated board.

Preferably, the first accommodating space is formed by recessing a lower surface of the first prefabricated board, or is formed by recessing an upper surface of the second prefabricated board; and the second accommodating space is formed by recessing a lower surface of the second prefabricated board, or is formed by recessing an upper surface of the third prefabricated board.

Preferably, the high-integrated substrate, further comprising an element disposed on a lower surface of the first prefabricated board and/or an upper surface of the third prefabricated board.

Preferably, an element provided on the upper surface of the third prefabricated board comprises a capacitor; the third prefabricated board further comprises a surface wiring layer on the upper surface, a surface wiring layer on the lower surface, a first wiring layer and a second wiring layer adjacent to the first wiring layer; the surface wiring layer on the upper surface and the surface wiring layer on the lower surface both comprise a positive end pad and a negative end pad, the first wiring layer and the second wiring layer both comprise a copper spreading layer, the positive end pad of the upper surface, the copper spreading layer of the first wiring layer, and the positive end pad of the lower surface are electrically connected by means of a via hole; the negative end pad of the upper surface, the copper spreading layer of the second wiring layer, and the negative end pad of the lower surface are electrically connected by means of a via hole; the copper spreading layer of the first wiring layer and the copper spreading layer of the second wiring layer overlap each other; the positive end pad is electrically connected to the positive end of the capacitor, and the negative end pad is electrically connected to the negative end of the capacitor.

Preferably, the high-integrated substrate forms a plate edge metal by means of a plate edge metallization process, and the plate edge metal is connected to a surface wiring layer on the upper surface and/or a surface wiring layer on the lower surface of the high-integrated substrate.

Preferably, the plate edge metal is electrically connected to the conductive connector and the winding.

Preferably, the plate edge metallization process comprises:

plating metal on the high-integrated substrate, and providing a tin-plated layer on the metal;

at part of the position on the side wall of the high-integrated substrate, the tin-plated layer is removed by mechanical, laser, etc. and then the exposed excess metal is etched away.

Preferably, the winding comprises embedded thick copper embedded in the second prefabricated board, and any one of the upper surface, the lower surface or the side wall of the thick copper is exposed on the surface of the second prefabricated board.

Preferably, wherein the windings are a plurality of windings connected in parallel.

Preferably, the winding is a special-shaped copper material, the special-shaped copper material comprises a horizontal portion and two vertical portions, and end surfaces of the two vertical portions are respectively exposed on an upper surface and a lower surface of the second prefabricated board.

Preferably, wherein the conductive connector is formed gradually added step-by-step through a blind groove plating process.

Preferably, the conductive connector comprises a copper block, a via hole, and a conductive bonding material; the copper block is disposed in the third prefabricated board, the via hole is disposed in the second prefabricated board, and the via hole and the copper block are connected by a conductive bonding material.

Preferably, substrate further comprising an outer wiring layer, wherein the outer wiring layer is provided on an upper surface of the first prefabricated board or a lower surface of the third prefabricated board; the outer wiring layer comprises at least one wiring layer, and the at least one wiring layer is electrically connected to the prefabricated board by means of a blind hole or a through hole.

Preferably, the high-integrated substrate, further comprising a fourth prefabricated board, wherein the fourth prefabricated board is arranged between the first prefabricated board and the second prefabricated board or between the second prefabricated board and the third prefabricated board, and the fourth prefabricated board is bonded to the first prefabricated board and the second prefabricated board or the second prefabricated board and the third prefabricated board by means of a bonding medium, respectively; further comprising a third accommodating space, wherein the third accommodating space is disposed between the first prefabricated board and the fourth prefabricated board or between the third prefabricated board and the fourth prefabricated board, and at least one element is disposed in the third accommodating space.

Preferably, the fourth prefabricated board is provided with an exhaust channel.

Preferably, the high-integrated substrate, comprising a fourth prefabricated board, wherein the fourth prefabricated board is arranged between the first prefabricated board and the second prefabricated board, and the fourth prefabricated board is bonded to the first prefabricated board and the second prefabricated board respectively by means of a bonding medium; further comprising a third accommodating space, a fourth accommodating space, and another magnetic assembly; the third accommodating space is disposed between the first prefabricated board and the fourth prefabricated board, and the fourth accommodating space is disposed between the fourth prefabricated board and the second prefabricated board; the another magnetic assembly includes a winding, an upper magnetic cover, a lower magnetic cover, and at least two magnetic columns; the winding is disposed in the fourth prefabricated board, the fourth prefabricated board further includes at least two opening windows for the magnetic columns of the another magnetic assembly to pass through, the upper magnetic cover of the another magnetic assembly is disposed in the third accommodating space, and the lower magnetic cover of the another magnetic assembly is disposed in the fourth accommodating space.

Preferably, wherein the fourth prefabricated board is provided with an exhaust channel.

Preferably, comprising a fourth prefabricated board, wherein the fourth prefabricated board is arranged between the first prefabricated board and the second prefabricated board, and the fourth prefabricated board is bonded to the first prefabricated board and the second prefabricated board respectively by means of a bonding medium; further comprising a third accommodating space, a fourth accommodating space, and another magnetic assembly; the third accommodating space is disposed between the first prefabricated board and the fourth prefabricated board, and the fourth accommodating space is disposed between the fourth prefabricated board and the second prefabricated board; the another magnetic assembly includes a winding, an upper magnetic cover, a lower magnetic cover, and at least two magnetic columns; the winding is disposed in the fourth prefabricated board, the fourth prefabricated board further includes at least two opening windows for the magnetic columns of the another magnetic assembly to pass through, the upper magnetic cover of the another magnetic assembly is disposed in the third accommodating space, and the lower magnetic cover of the another magnetic assembly is disposed in the fourth accommodating space.

Preferably, wherein the number of the magnetic assembly is at least two, each of the magnetic assemblies is correspondingly provided with an independent first accommodating space and an independent second accommodating space, each of the magnetic assemblies is correspondingly provided with an independent winding, and the windings of the magnetic assemblies are not electrically connected.

Preferably, the number of the magnetic assembly is at least two, each of the magnetic assemblies is correspondingly provided with an independent first accommodating space and an independent second accommodating space, each of the magnetic assemblies is correspondingly provided with an independent winding, and the windings of the magnetic assemblies are not electrically connected.

Preferably, there are at least two magnetic assemblies, each of the magnetic assemblies is correspondingly provided with an independent first accommodating space and an independent second accommodating space, each magnetic assembly is correspondingly provided with an independent winding, and a semi-cutting groove is provided between two adjacent magnetic assemblies.

Preferably, the number of the opening windows is four, the magnetic assembly comprises four magnetic columns and four windings, each of the windings is arranged around one magnetic column, and the length L of the winding is greater than the thickness H of the upper magnetic cover.

A power module, comprising a high-integrated substrate, and further comprising a power semiconductor and a capacitor, wherein the power semiconductor and the capacitor are arranged on an upper surface of the high-integrated substrate, and the power semiconductor is electrically connected to the winding by means of a pad and a conductive connector provided on an upper surface of the high-integrated substrate.

Preferably, the lower surface of the third prefabricated board is provided with a pad; the capacitor is electrically connected to the pad of the lower surface of the third prefabricated board by means of the conductive connector; and the power semiconductor is electrically connected to the pad of the lower surface of the third prefabricated board by means of the conductive connector.

Preferably, the power module, further comprising a driver chip disposed on a lower surface of the first prefabricated board.

Preferably, the power module, further comprising an output capacitor disposed on an upper surface of the third prefabricated board.

Preferably, the power module is configured to supply power vertically, and is disposed on a surface of the main board of the system and supplies power to an integrated circuit disposed on the other side of the main board of the system.

The manufacturing method of the high-integrated substrate, comprising the following steps:
Step 1, fabricating a first prefabricated board, a second prefabricated board and a third prefabricated board, processing a first accommodating space on the lower surface of the first prefabricated board or the upper surface of the second prefabricated board, processing a second accommodating space on the lower surface of the second prefabricated board or the upper surface of the third prefabricated board, and processing at least two windows in communication with the first accommodating space and the second accommodating space on the second prefabricated board;
Step 2, assembling a magnetic core on the second prefabricated board;
Step 3, laminating the first prefabricated board and the third prefabricated board by means of a bonding medium stack on an upper surface and a lower surface of the second prefabricated board to form a laminate;
Step 4, vertically punching a via hole on the laminate, electroplating a sidewall of the via hole, and electrically connecting a corresponding wiring layer;
Step 5, drilling a hole in an upper wall of the first prefabricated board and/or in a side wall of the first prefabricated board or the second prefabricated board to the first accommodating space to form an exhaust channel.

The manufacturing method of the high-integrated substrate, comprising the following steps:
Step 1, prefabricated first prefabricated boards, second prefabricated boards, and third prefabricated boards, the first accommodating space and the second accommodating space being respectively processed on the upper surface and the lower surface of the second prefabricated board, and at least two windows in communication with the first accommodating space and the second accommodating space are processed on the second prefabricated board; and an element is provided on the lower surface of the first prefabricated board, a magnetic core is assembled on the second prefabricated board, and an element is provided on the upper surface of the third prefabricated board;
Step 2: disposing a bonding medium on an upper surface and a lower surface of the second prefabricated board, and partially curing.
Step 3, removing a bonding medium at a position corresponding to the upper magnetic cover and the lower magnetic cover of the magnetic core; laminating the first prefabricated board, the second prefabricated board, and the third prefabricated board;
Step 4, vertically punching a via hole on the laminate, electroplating a sidewall of the via hole, and electrically connecting a corresponding wiring layer;
Step 5: drilling the first prefabricated board to a first accommodating space to form an exhaust channel.

Compared with the prior art, the application has the following beneficial effects:
(1) The present invention provides a high-integrated substrate, which is laminated and stacked by means of a plurality of prefabricated boards, achieves electrical connection between the prefabricated boards by means of the conductive connectors, reduces the solder joints and connection paths between layers, and further improves the space utilization rate of the substrate in the plane and the height direction by means of arranging the elements in the substrate;
(2) In the present invention, the part of the magnetic core is arranged in the accommodating space, and the accommodating space is in communication with the external space by means of the exhaust channel, so as to reduce the working temperature of the magnetic core assembly and improve the working performance of the magnetic core assembly, and at the same time, the reliability of the substrate in the service process is improved.

### BRIEF DESCRIPTION OF THE DRAWINGS

FIG. 1 is a schematic diagram of a high-integrated substrate.

FIG. 2A to FIG. 2G are process steps of a high-integrated substrate.

FIG. 3A to FIG. 3C are schematic diagrams of another high-integrated substrate.

FIG. 4A to FIG. 4F are process steps of another high-integrated substrate.

FIG. 5 is a distribution of wiring layers of a capacitor region.

FIG. 6A to FIG. 6D are plate edge metallization of a high-integrated substrate.

FIG. 7A to FIG. 7E are extended embodiments of windings and conductive connectors.

FIG. 8 is an embodiment of adding an outer wiring layer.

FIG. 9A to FIG. 9C are high-integrated substrates of a plurality of units.

FIGS. 10A-10B are embodiments for adding a fourth prefabricated board.

FIG. 11A to FIG. 11B are power modules using a high-integrated carrier plate.

FIG. 12A and FIG. 12B are a system application of a high-integrated substrate.

### DESCRIPTION OF THE EMBODIMENTS

One of the cores of the present invention is to provide a substrate having a high integrated level and a power module.

Technical solutions in the embodiments of the present disclosure will be clearly and completely described below with reference to the accompanying drawings in the embodiments of the present disclosure. Apparently, the described embodiments are merely some rather than all of the embodiments of the present disclosure. All other embodiments obtained by a person of ordinary skill in the art based on the embodiments of the present disclosure without creative efforts shall fall within the protection scope of the present disclosure.

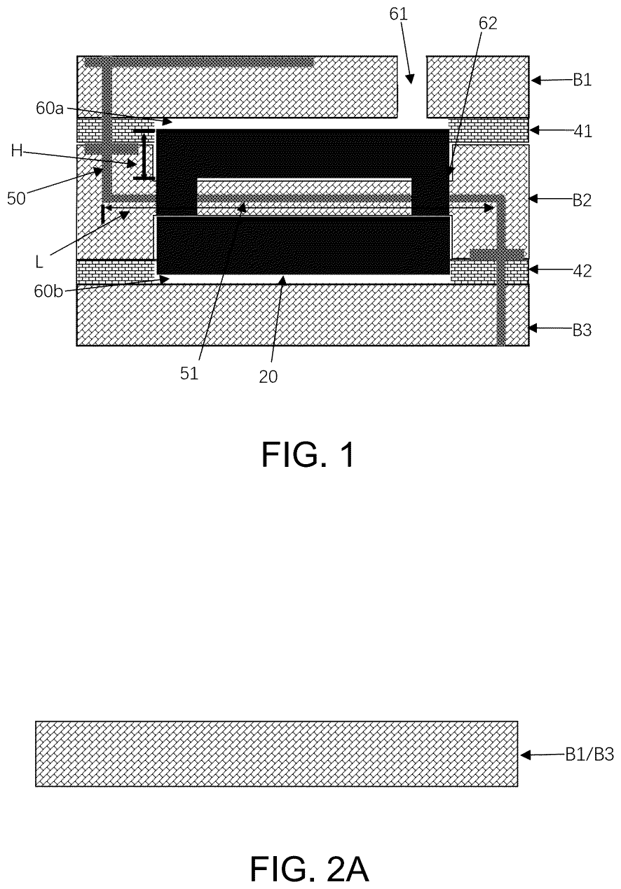

The substrate with a high-integrated disclosed in the present invention is shown in FIG. 1, and comprises a first prefabricated board B1, a second prefabricated board B2, and a third prefabricated board B3. The prefabricated board herein may be a printed circuit board, but is not limited thereto, and may also be another circuit substrate. The first prefabricated board B1 and the second prefabricated board B2 are fixedly connected by means of a bonding medium 41, and the second prefabricated board B2 and the third prefabricated board B3 are fixedly connected by means of a bonding medium 42. The second prefabricated board B2 comprises an upper surface and a lower surface opposite to each other. The upper surface and the lower surface are provided with accommodating spaces 60a and 60b respectively, and the accommodating spaces 60a and 60b are formed by recessing the upper surface and the lower surface into the interior of the second prefabricated board respectively. The second prefabricated board B2 further comprises at least two opening windows 62 and a horizontal wiring layer 51, and the opening window 62 vertically penetrates the second prefabricated board B2 and is in communication with the accommodating spaces 60a and 60b. The accommodating spaces 60a and 60b are used for accommodating the magnetic core assembly 20, and the magnetic core assembly comprises an upper magnetic cover, a lower magnetic cover, and at least two magnetic columns; and the magnetic column of the magnetic core assembly 20 passes through the corresponding opening window 62 and is assembled with the horizontal wiring layer 51 arranged inside the second prefabricated board B2 to realize magnetic coupling. The horizontal wiring layer 51 is electrically connected to the conductive connector 50 provided in the second prefabricated board B2, the first prefabricated board B1 or the third prefabricated board B3; the horizontal wiring layer 51 may be a wiring layer provided inside the second prefabricated board B2, or may be a metal layer provided on the surface of the second prefabricated board B2, and the horizontal wiring layer is a part of the winding. The length of the horizontal wiring layer 51 is L, and the thickness of the upper magnetic cover is H; since the horizontal winding is formed by the horizontal wiring layer of the PCB, the continuity of the copper is good (a very high copper laying rate can be achieved in the plane direction), and therefore has a relatively low impedance. The vertical connection is realized in the form of via holes, etc. and the continuity is poor; therefore, the length of the vertical connecting portion needs to be reduced as much as possible, so as to obtain optimal performance. Thus, the design herein is that L≥H. The first prefabricated board B1 includes an exhaust channel 61, and the exhaust channel 61 vertically penetrates through the upper surface and the lower surface of the first prefabricated board B1 and is in communication with the accommodating space 60a. In the present embodiment, the outer surface of the magnetic core assembly 20 and the inner wall of the accommodating space 60a and 60b retain a certain gap, the accommodating space can also be open to the outside by means of the exhaust channel 61, and the heat generated by the magnetic core assembly can escape through the gap and the exhaust channel, thereby reducing the working temperature of the magnetic core assembly. Optionally, a soft colloid, such as a silicone gel, can also be provided in the accommodating space, so that the heat dissipation performance can be further increased without causing degradation of the magnetic performance.

In the conventional technology, the thickness of the copper layer in the wiring layer is generally limited by embedding the magnetic core assembly in the any layer structure. In the present embodiment, a plurality of prefabricated boards are fixedly connected by means of bonding, and the magnetic core assembly is placed in the substrate, which breaks the limitation of the copper thickness of the wiring layer by the traditional process. In addition, the laminated structure of each prefabricated board can be freely arranged according to requirements (for example, a conventional via plate, a buried hole plate, a stacked hole plate, or even any layer of interconnection plate, so as to fully exert the advantages of various stacked structures), and the performance of the power module can be effectively improved, and the cost of the product is reduced. On the other hand, the magnetic core assembly is arranged in the accommodating space, and the outer surface of the magnetic core assembly and the inner wall of the accommodating space retain a certain gap, thereby avoiding the increase of the magnetic loss and the lower temperature cycle life caused by the mismatch of the thermal expansion coefficient of the magnetic core material and the PCB material in the conventional magnetic core embedded process. The accommodating space can also be open to the outside through the exhaust channel. The horizontal portion of the winding of the magnetic assembly is provided by means of the horizontal wiring layer of the prefabricated board, thereby the continuity of copper (i.e. having a better space utilization rate) is better utilized. Compared with the traditional embedded magnetic core technology, for example, by using a via hole to form the main body portion of the winding, better magnetic performance can be obtained. On the other hand, the prefabricated boards are electrically connected by means of the conductive connectors, reducing the solder joints between layers in the vertical stacking module, effectively reducing the problem of welding failure, and improving the reliability and performance of the power module. Furthermore, the winding of the magnetic assembly is disposed on the upper surface and the lower surface of the second prefabricated board. For the vertically stacked substrate, the connection path with other components can be reduced, the loss of the current on the conduction path is reduced, and the energy transmission performance of the substrate is improved.

In this embodiment, the shape and length of the horizontal winding are merely illustrative, and the shape and length of the winding need to be determined according to the shape of the actual winding.

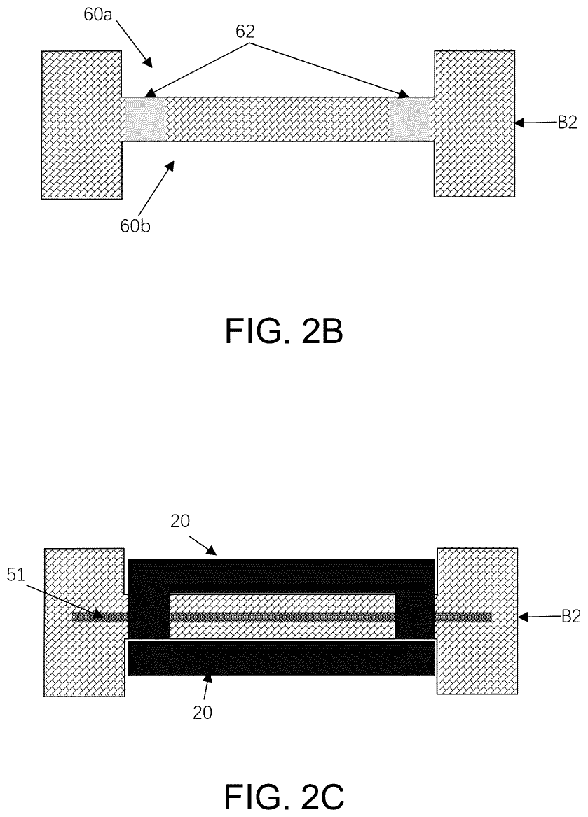

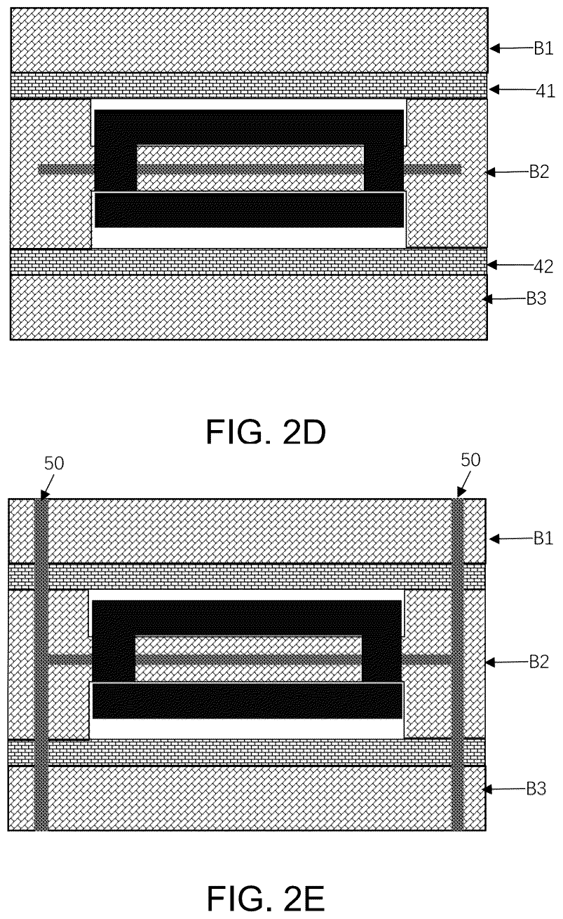

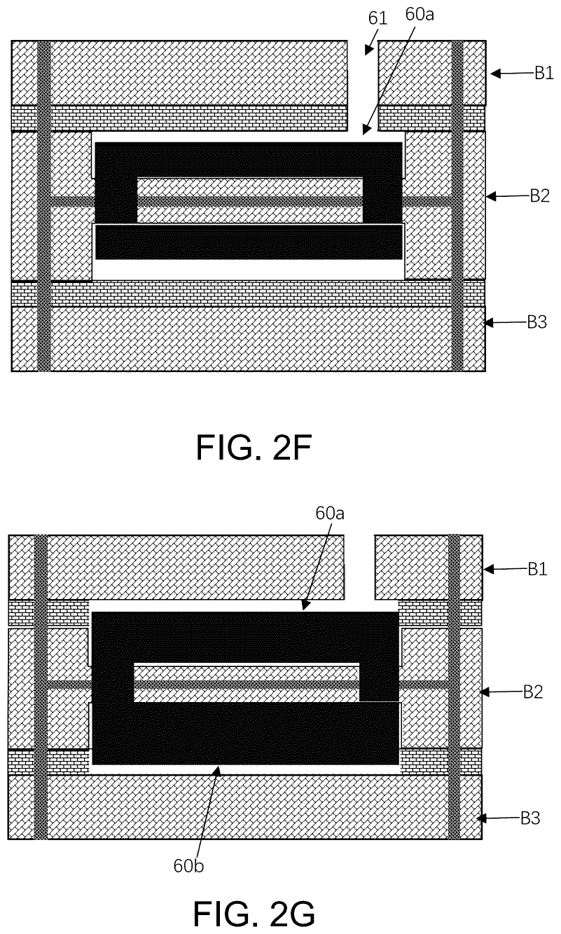

With respect to the substrate structure shown in FIG. 1, the present invention further discloses a corresponding process step, and the detailed steps are shown in FIGS. 2A-2G.

Step 1, fabricating a first prefabricated board B1 and a third prefabricated board B3, wherein the first prefabricated board B1 and the third prefabricated board B3 comprise wiring layers, as shown in FIG. 2A; fabricating a second prefabricated board B2, as shown in FIGS. 2B and 2C, wherein the second prefabricated board B2 comprises a horizontal wiring layer 51; the accommodating spaces 60a and 60b are processed on the upper surface and the lower surface of the second prefabricated board B2, and the opening windows 62 are processed to communicate the accommodating spaces 60a and 60b; each prefabricated board comprises a wiring layer (not shown)).

Step 2: assembling a magnetic core on the second prefabricated board B2, and bonding them into a magnetic core assembly 20 by means of a bonding material, as shown in FIG. 2C.

Step 3: laminating the first prefabricated board B1 and the third prefabricated board B3 through a bonding medium stack on the upper surface and the lower surface of the second prefabricated board B2 to form a laminate, wherein the bonding medium is preferably a prepreg (PP) laminated by the PCB, as shown in FIG. 2D.

Step 4: vertically punching holes on the laminate, electroplating the sidewalls, and electrically connecting corresponding wiring layers, as shown in FIG. 2E; and forming a surface pattern of the entire laminate in this step.

Step 5, drilling the first prefabricated board B1 to the accommodating space 60a to form an exhaust channel 61, as shown in FIG. 2F.

Optionally, in step 3, the bonding medium makes an avoidance at positions of the accommodating spaces 60a and 60b, as shown in FIG. 2G, so that the space utilization rate of the substrate in height can be further improved.

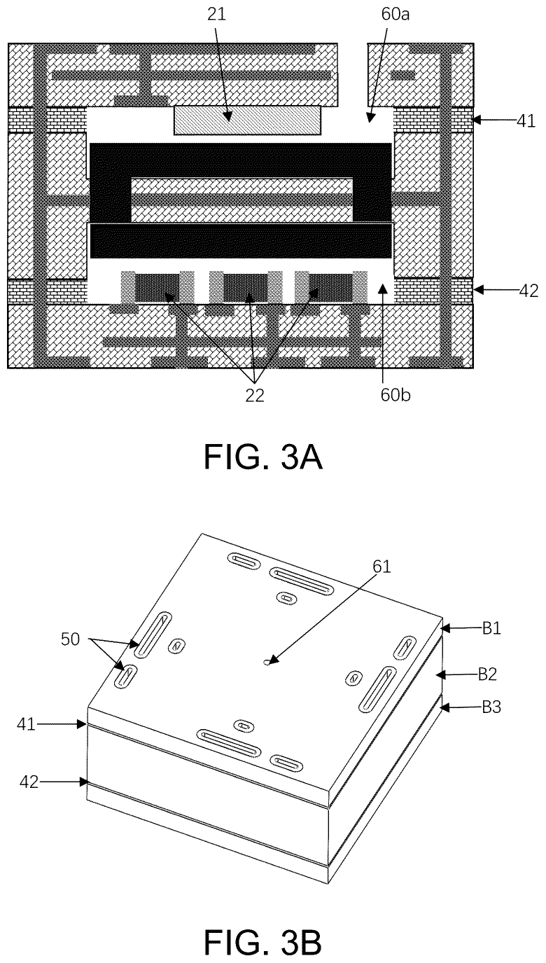

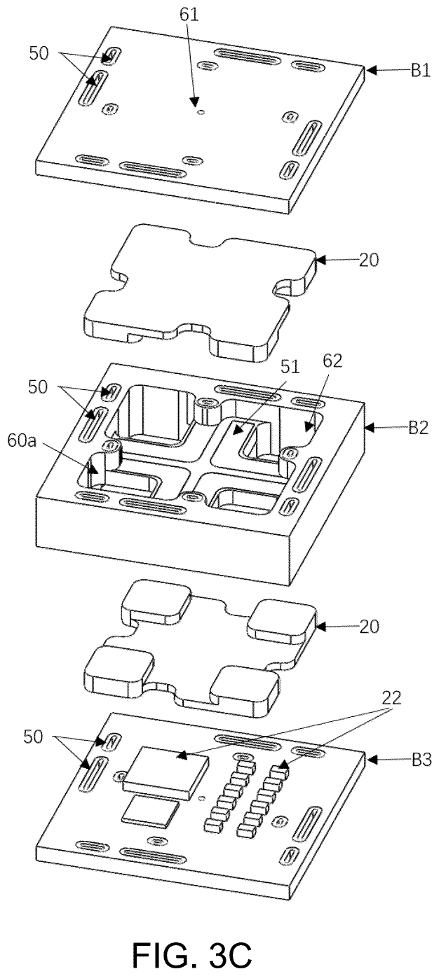

FIG. 3A to FIG. 3C show another embodiment, FIG. 3A is a side cross-sectional view of the embodiment, FIG. 3B is a three-dimensional schematic diagram of the embodiment, and FIG. 3C is an exploded schematic diagram of the embodiment. As shown in FIG. 3A, an element 21 may be disposed on the surface of the first prefabricated board B1 within the accommodating space 60a; similarly, an element 22 may also be disposed in the accommodating space 60b and on the surface of the second prefabricated board B2, as shown in FIG. 3A. By arranging the elements in the accommodating spaces, the size of the horizontal direction of the substrate can be effectively reduced by stacking the components in the vertical direction. Optionally, an element may be provided only on the surface of the prefabricated board in the accommodating space 60a or only on the surface of the prefabricated board in the accommodating space 60b.

Meanwhile, referring to the application shown in FIG. 3B and FIG. 3C, the application includes a first prefabricated board B1, a second prefabricated board B2, and a third prefabricated board B3. The first prefabricated board B1 and the second prefabricated board B2 are fixedly connected by means of a bonding medium 41, and the second prefabricated board B2 and the third prefabricated board B3 are fixedly connected by means of a bonding medium 42. The first prefabricated board B1 is provided thereon with an exhaust channel 61 and a conductive connector 50. The magnetic assembly comprising an upper magnetic cover, a lower magnetic cover, four magnetic columns, and four windings. An upper surface and a lower surface of the second prefabricated board B2 respectively comprise an accommodating space 60a and an accommodating space 60b (60b not shown) for accommodating the upper magnetic cover and the lower magnetic cover; further comprising four opening windows 62 for the magnetic columns of the magnetic core assembly to pass through; the four windings are disposed on the second prefabricated board B2, each winding is wound around an opening window, and the length L of each winding is the length of the winding path of the winding; the thickness of the upper magnetic cover is H, where L≥H. The conductive connector 50 is arranged on the side of the accommodating space and is electrically connected to the horizontal wiring layer 51; the four horizontal wiring layers 51 are arranged in the accommodating space and the surface of the second prefabricated board to be a winding part of the magnetic assembly; and the conductive connector 50 can penetrate through the upper surface and the lower surface of the second prefabricated plate B2, or can only penetrate one of the surfaces. The upper magnetic cover and the lower magnetic cover of the magnetic core assembly 20 are respectively provided in the accommodating spaces 60a and 60b, and are bucked with the second prefabricated board B2 and form a magnetic assembly with the horizontal wiring layer. An upper surface of the third prefabricated board B3 is provided with a plurality of elements 22, their setting positions are correspond to the accommodating spaces 60b, and the conductive connectors 50 are arranged around the plurality of elements 22. A conductive connector 50 on the first prefabricated board B1 is fixed and electrically connected to some or all of the conductive connectors 50 on the second prefabricated board B2, and a conductive connector 50 on the third prefabricated board B2 is fixed and electrically connected to some or all of the conductive connectors 50 on the second prefabricated board B2. In the three-dimensional schematic diagram shown in FIG. 3B and FIG. 3C, details such as some surface circuit diagrams or conductive connectors are not shown, and some via structures may also continue to be fabricated after the prefabricated boards B1/B2/B3 are stacked.

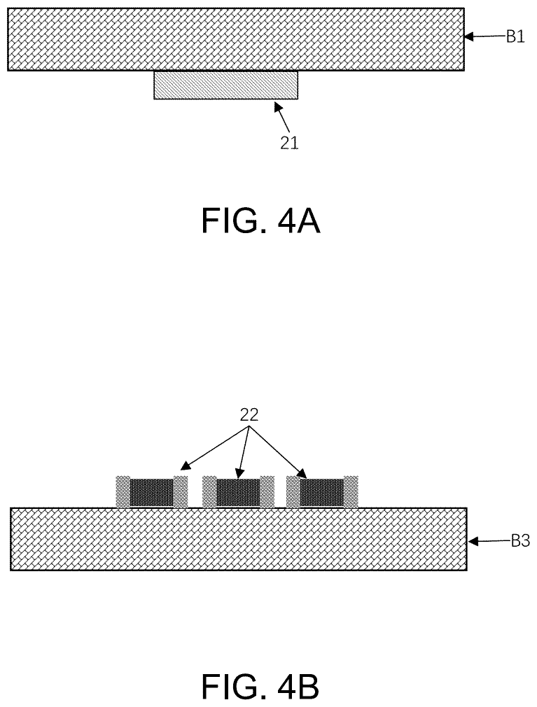

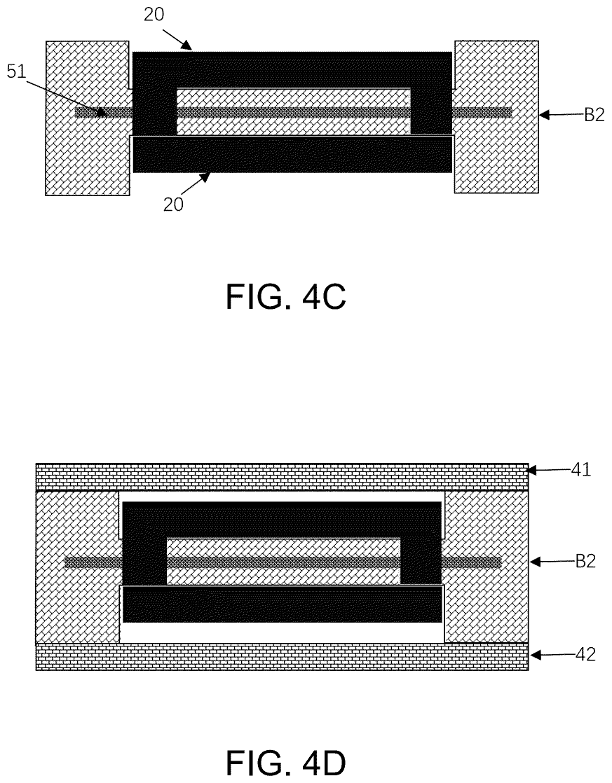

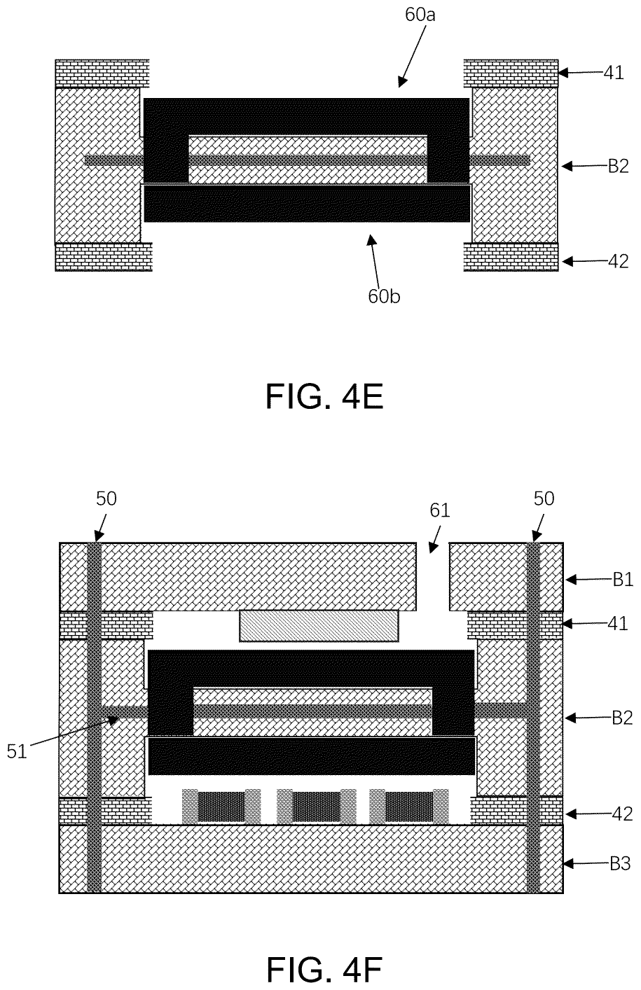

For the embodiments shown in FIG. 3A to FIG. 3C, the present disclosure further discloses a corresponding process step, and the detailed steps are shown in FIGS. 4A-4F.

In step 1, the first prefabricated board B1, the second prefabricated board B2, and the third prefabricated board B3 are prefabricated according to Step 1 in the previous embodiment, the first prefabricated board B1, the second prefabricated board B2, and the third prefabricated board B3 are all provided a wiring layer, and an element 21 is disposed on the lower surface of the first prefabricated board B1, as shown in FIG. 4A. An element 22 is provided on the upper surface of the third prefabricated board B3, as shown in FIG. 4B; and according to Step 2 in the previous embodiment, the magnetic core assembly 20 is assembled on the second prefabricated board B2 as shown in FIG. 4C.

Step 2: disposing a bonding medium on the upper surface and the lower surface of the second prefabricated board B2, the prepreg is optimal with partial curing applied, as shown in FIG. 4D.

In step 3, the prepregs at positions corresponding to the upper magnetic cover and the lower magnetic cover of the magnetic core assembly 20 are removed, and the laser removal method is optimal; the cutting edge may be slightly beyond the side wall of the accommodating space, that is, a part of the prepregs cover the edge positions of the accommodating spaces 60a and 60b, so as to avoid undesirable phenomena such as lamination, as shown in FIG. 4E. Then laminating the first prefabricated board B1, the second prefabricated board B2, and the third prefabricated board B3.

Next, Step 4 and Step 5 in the previous embodiment are performed, as shown in FIG. 4F.

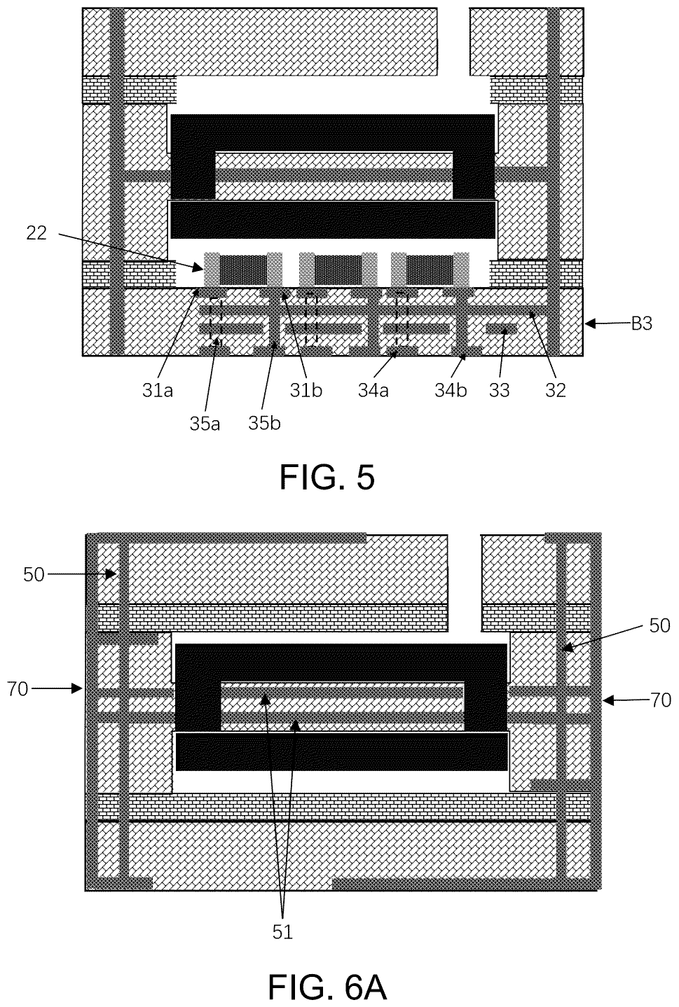

In the structure shown in the present embodiment, the element 22 may be a plurality of capacitors connected in parallel. As shown in FIG. 5, in the capacitor arrangement area, the surface wiring layer on the upper surface of the third prefabricated board, the surface wiring layer on the lower surface, the first wiring layer and the second wiring layer adjacent to the upper surface, are provided with a copper layer at the same potential with two ends of the capacitor, respectively. For example, the copper layer 32 of the first wiring layer, the positive end pad 31a (electrically connected to the positive end of the capacitor) of the upper surface and the positive end pad 34a of the lower surface have the same potential, and are electrically connected by means of the via hole 35a; the copper layer 33 of the second wiring layer, the negative end pad 31b (electrically connected to the capacitor negative end) of the upper surface and the negative end pad 34b of the lower surface have the same potential, and are electrically connected by means of the via hole 35b. The copper layers of the first wiring layer and the second wiring layer overlap each other (necessary inter-layer connection via holes need to be avoided correspondingly). By means of such a layout structure, electrodes at the same potential at two ends of the capacitor are led out to the surface of the substrate. Furthermore, by means of adjacent stacked wiring, parasitic parameters between the parallel capacitors are reduced, so that the performance of the equivalent parallel capacitors is sufficiently improved. The capacitor shown in the present embodiment may be an output capacitor of a module, and the output capacitor may also be a load filter capacitor; or two different capacitors, which are respectively routed and electrically connected by using the layout structure. Optionally, the copper layers at the same potential at two ends of the capacitor can also be respectively arranged in any adjacent layer of the prefabricated board B3, and parasitic parameters between the parallel capacitors are reduced by means of adjacent stacked wires, so that the performance of the equivalent parallel capacitors is sufficiently improved.

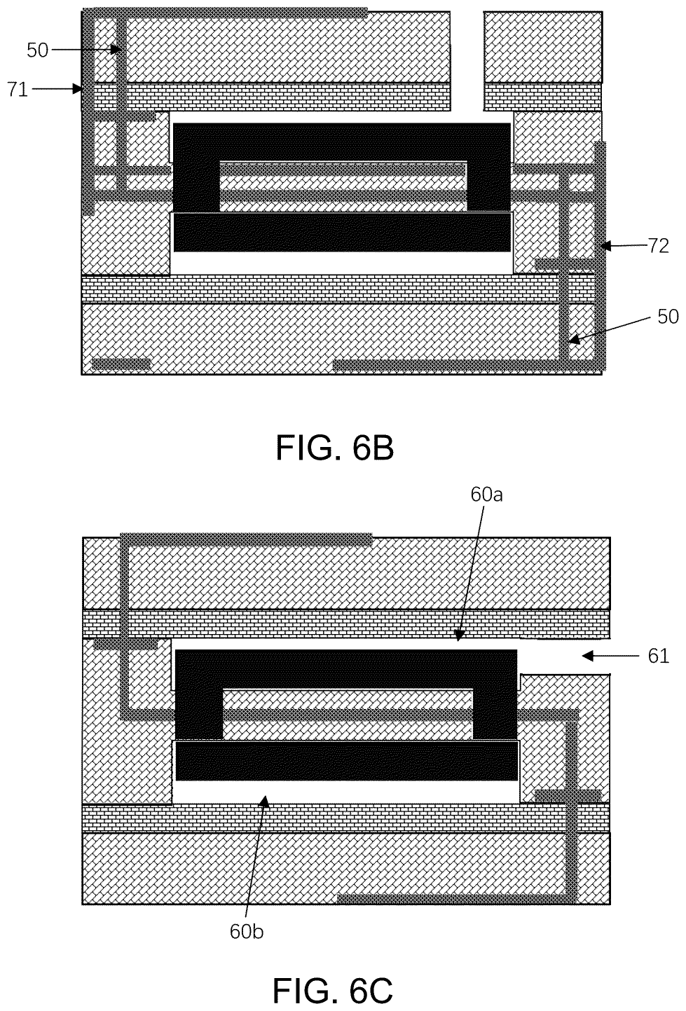

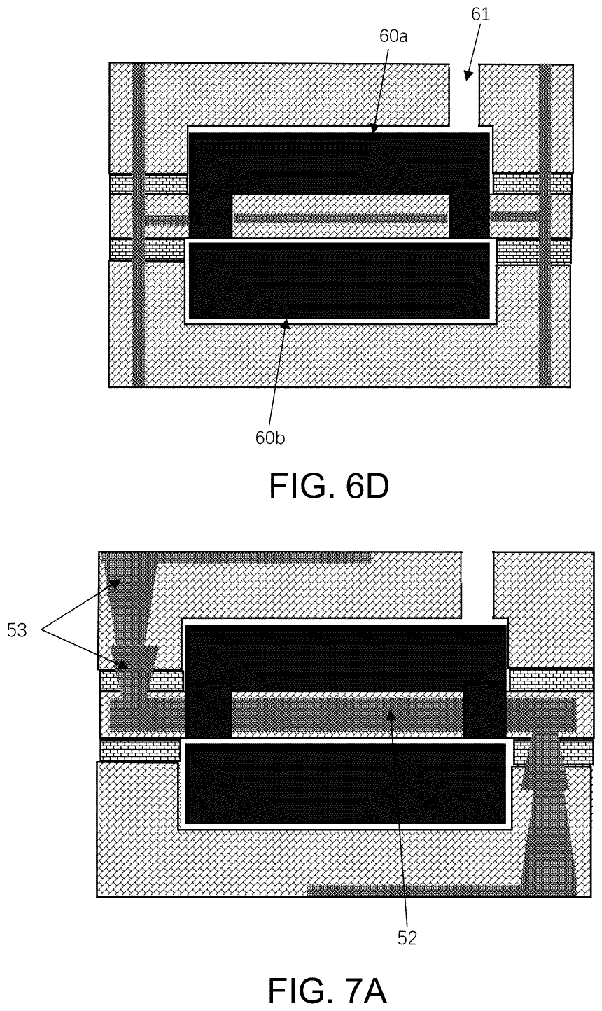

As shown in FIG. 6A and FIG. 6B, in the embodiments disclosed in the present disclosure, the impedance of the two ends of the winging in the vertical direction could be further reduced by means of edge metallization to connect with a surface wiring layer of the upper surface of the substrate and/or a surface wiring layer of the lower surface of the substrate. In detail, as shown in FIG. 6A, the two ends of the horizontal wiring layer 51 (i.e. the winding) are electrically connected to the board edge metal 70 respectively, the board edge metal 70 is electrically connected upward to the surface wiring layer of the upper surface, and is electrically connected downward to the surface wiring layer of the lower surface; and the board edge metal 70 is electrically connected in parallel to the conductive connector 50. Further, as shown in FIG. 6B, the board edge metal is only arranged in the effective area of the board edge height direction, so as to further improve the board utilization rate. In detail, the two ends of the horizontal wiring layer 51 are each electrically connected to the board edge metal 71 and 72, the board edge metal 71 is electrically connected upward to the surface wiring layer of the upper surface, the board edge metal 72 is electrically connected downward to the surface wiring layer of the lower surface, and the board edge metal 71 and 72 are electrically connected in parallel to the corresponding conductive connector 50, respectively. In the present embodiment, the horizontal wiring layer 51 is two layers, through the parallel connection of the two wiring layers, the loss of the winding is reduced. Here, the two wiring layers are only schematic, and may also be multi-wiring layers connected in parallel.

According to the edge metallization process disclosed in the present invention, firstly, perform edge metallization on the sidewall of the substrate, substrate then a tin plating layer is arranged on the metal, and then the tin protection layer is removed using mechanical, laser, or other methods at the position without the need for metal placement on the side wall, and then the exposed excess metal is etched away. Preferably, the metal is copper.

In the embodiments disclosed in the present invention, the exhaust channel 61 can also be provided on the side wall of the substrate, as shown in FIG. 6C, and the position of the exhaust channel 61 can be provided in communication with the accommodating space 60a and/or 60b. The advantage of providing the exhaust channel on the side edge is that the integrity of the upper surface and the lower surface of the substrate can be ensured, and the use area of the surface-mountable element can be improved. By means of the arrangement method for the sidewall exhaust channel, part of the side wall is milled during the manufacturing process of the second prefabricated board B2, and is in communication with the accommodating space.

In another embodiment, the accommodating space may be formed by controlled-depth milling on the surface of the first prefabricated board and/or the third prefabricated board. As shown in FIG. 6D, the accommodating space 60a is formed by controlled-depth milling at the lower surface of the first prefabricated board B1; and the accommodating space 60b is formed by controlled-depth milling on the upper surface of the third prefabricated board B3. In other embodiments, an accommodating space may be disposed on the first prefabricated board or the third prefabricated board, and the other accommodating space may be correspondingly disposed on the lower surface or the upper surface of the second prefabricated board. Similarly, the exhaust channel 61 can also be provided on the side wall of the first prefabricated board and/or the side wall of the third prefabricated board by using the same method, and same technical benefits can also be obtained, and details are not described again. Therefore, in the present invention, the accommodating space can be flexibly arranged according to the thickness or the stacking manner of the three prefabricated boards, so that the production difficulty of the prefabricated board is reduced, and the overall performance of the substrate is improved, for example, a more reasonable via thickness ratio can be obtained.

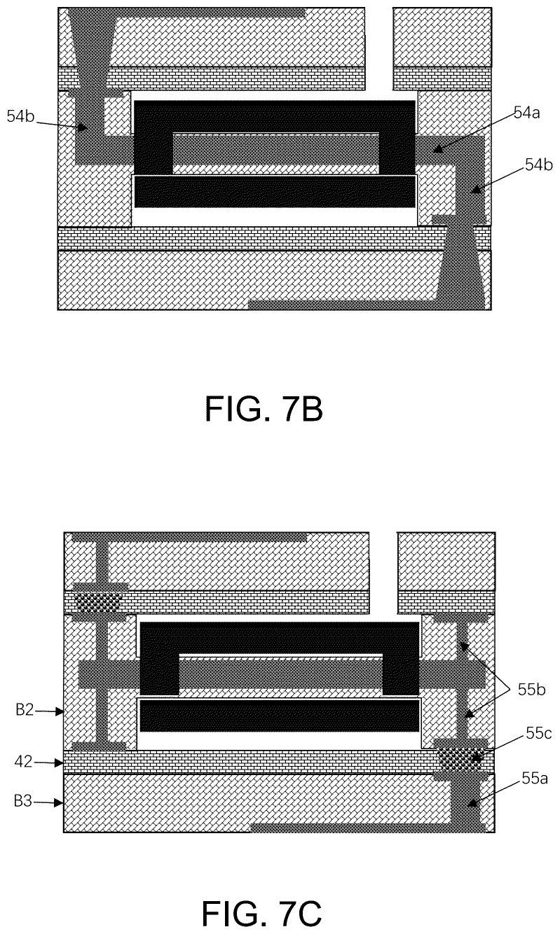

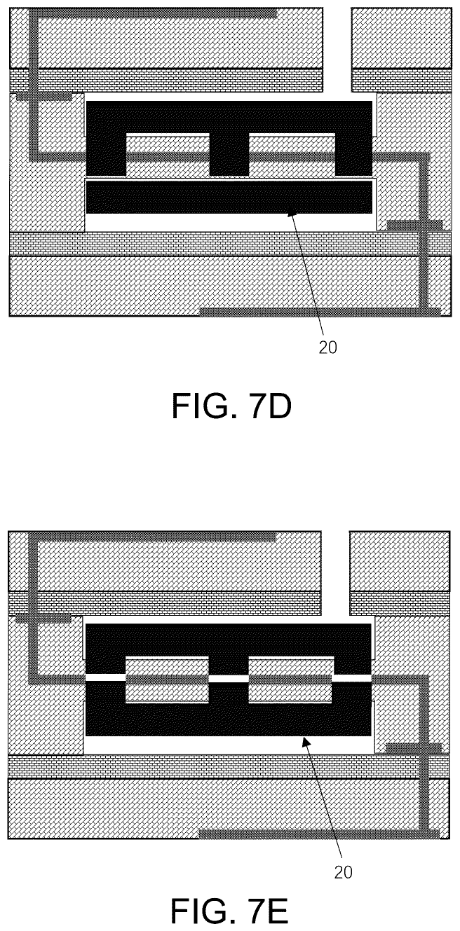

FIGS. 7A-7C illustrate another embodiment of a winding and a conductive connection. With reference to FIG. 7A to FIG. 7C, the winding 52 can be realized by embedding a thick copper material in the second prefabricated board B2. The increasing thickness of the winding 52, compared with using a multi-wiring layer in parallel, make a reduction of the insulating medium between the wiring layers, thereby achieving the purpose of reducing the impedance of the winding. Further, the upper and/or lower surfaces and/or sidewalls of the winding may each be exposed to a surface of the second prefabricated board B2.The implementation method can be achieved by providing redundancy in the height direction and/or width direction when the prefabricated boards are overlapped, and then exposing one or more of the upper surface, the lower surface or the sidewall of the winding during the shape processing stage; thus, the space utilization rate of the second prefabricated board B2 is further improved, and the impedance of the winding is further reduced. In addition, when a plurality of windings are arranged in parallel, a process of etching the upper surface and the lower surface of the second prefabricated board B2 respectively can be used to reduce the distance between the windings, thereby further increasing the effective width of the winding. On the other hand, the conductive connector can also be gradually added step by step by means of a blind groove plating process; as shown in FIG. 7A, the conductive connector is realized by means of superposition of two blind grooves 53. The use of the blind groove process can effectively increase the co-current capability, and by means of segmented superposition can effectively reduce the aspect ratio of the blind groove, which is more conductive to the electroplating of the blind groove. In addition, compared with the through hole structure, the blind groove process can be used to reduce the space waste at the remaining positions in the vertical direction, thereby improving the wiring density of the substrate.

In other embodiments, the winding may also employ a special-shaped copper material, further reducing winding impedance. As shown in FIG. 7B, the Z-shaped copper material 54 is prefabricated in the second prefabricated board B2, that is, the Z-shaped copper material includes a horizontal portion 54a and two vertical portions 54b, the two vertical portions 54b are replaced with some of the conductive connectors, and the end surfaces of the two vertical portions are exposed to the upper surface and the lower surface of the second prefabricated board, respectively; of course, the shape of the copper material is not limited to Z-shape, and can be designed according to actual requirements.

In other embodiments, the conductive connector can also be implemented in such a manner as to select a via hole or a prefabricated copper block according to the thickness of the prefabricated board, and the purpose thereof is to make each prefabricated board have a lower thickness-to-diameter ratio, which is easy to increase the copper thickness of the vertical connection portion, thereby reducing the difficulty of the process. As shown in FIG. 7C, the conductive connection comprises a copper block 55a, a via hole 55b, and a conductive bonding material 55c; the copper block 55a is disposed in the third prefabricated board B3, the via hole 55b is disposed in the second prefabricated board B2, and the via hole 55b and the copper block 55a are connected by means of a conductive bonding material 55c. Here, the conductive bonding material 55c may be a sintered material (such as sintered silver, copper, etc.), a conductive paste, solder, etc. The method for implementing the conductive bonding material 55c comprises: after the bonding medium 42 is semi-cured, using a laser to open a window at a corresponding position on the bonding medium 42, then providing a conductive bonding material by means of printing or other method, and finally laminating the second pre-fabricated board B2 and the third prefabricated board B3 by means of a bonding medium 42 to cure the bonding medium 42 while completing the molding of the conductive bonding material.

In the embodiments disclosed in the present disclosure, the magnetic core assembly 20 may be in a UI shape as shown in the above embodiments, or may be an EI shape as shown in FIG. 7D, or may be an EE shape as shown in FIG. 7E, or a 4-column or 5-column magnetic core assembly may also be used. The number of windings corresponding to the magnetic core assembly and the coupling relationship between different windings can all be set as required.

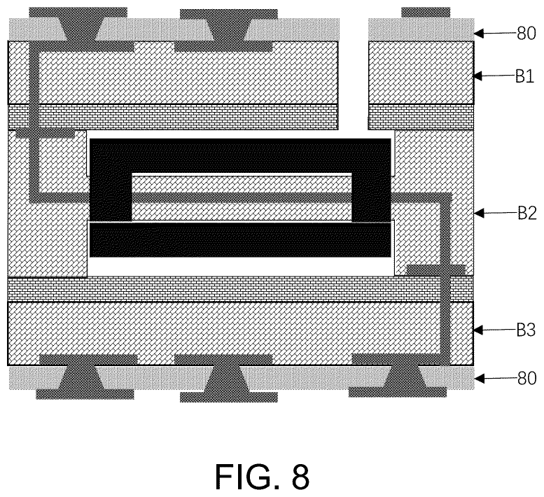

In the embodiments disclosed in the present invention, one or more outer wiring layers 80 may also be stacked on the upper surface of the first prefabricated board B1 and the lower surface of the third prefabricated board B3, as shown in FIG. 8; the wiring flexibility is increased; the added outer wiring layer 80 and the prefabricated board wiring layer may be connected by means of blind holes, through holes, and the like.

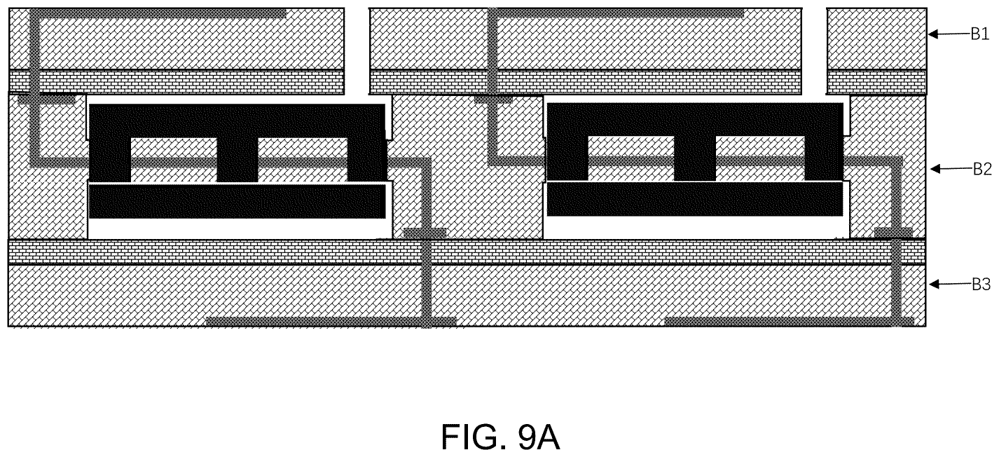

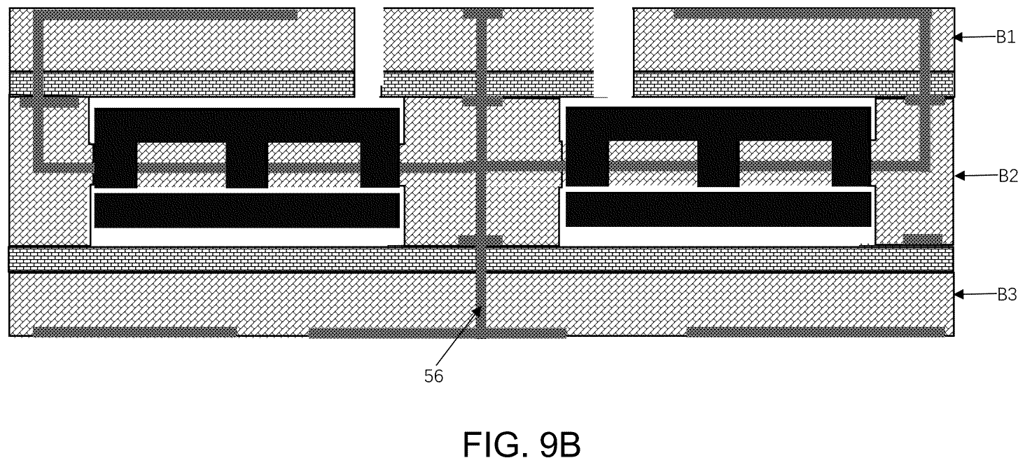

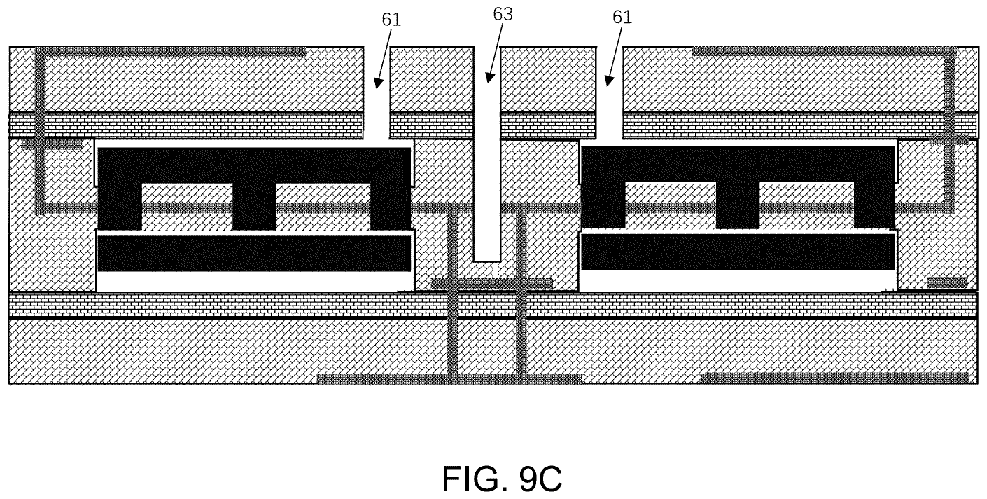

In other embodiments, two or more magnetic assemblies may also be provided in the substrate, as shown in FIGS. 9A and 9B. In FIG. 9A, the two magnetic assemblies are independent of each other, the corresponding accommodating space is independently arranged, and the windings of the two magnetic assemblies are not electrically connected on the substrate. In FIG. 9B, the dotted terminals of the windings in the two magnetic assemblies are electrically connected to the conductive connector 56 on the substrate. A semi-cutting groove 63 can also be provided between two adjacent units, as shown in FIG. 9C, the two windings can be electrically connected by means of the conductive connector and the wiring layer. The arrangement of the semi-cutting grooves on the one hand can release the stress of the substrate body, and at the same time avoid the influence of the high stiffness of the substrate itself on the system board, for example, causing system board warping and the like.

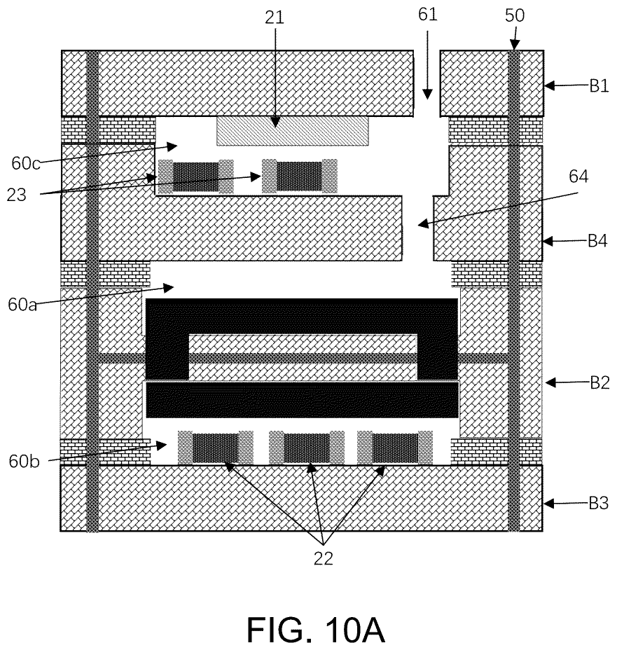

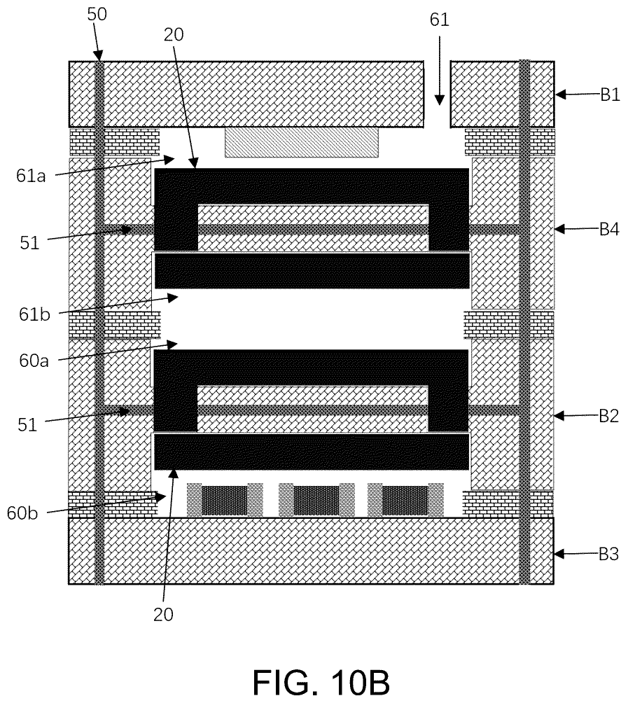

According to the embodiments disclosed in the present invention, a fourth prefabricated board B4 could also be added, and the fourth prefabricated board B4 may be disposed adjacent to the second prefabricated board B2, and may be disposed on the upper surface or the lower surface of the second prefabricated board B2. As shown in FIGS. 10A and 10B, the fourth prefabricated board B4 is disposed between the first prefabricated board B1 and the second prefabricated board B2, the accommodating space 60c is formed by recessing the fourth prefabricated board B4, the element 23 is disposed in the accommodating space 60c, and is fixed on the upper surface of the fourth prefabricated board B4. The fourth prefabricated board B4 further comprises an exhaust channel 64, the exhaust channel 64 being in communication with the accommodating space 60a and the 60c. The element 21 is also provided in the accommodating space 60c and is fixed on the lower surface of the first prefabricated board B1. The first prefabricated board B1 further comprises an exhaust channel 61, and the exhaust channels 61 and 64 may be vertically penetrating, or may be arranged at different positions and staggered with each other. The two adjacent prefabricated boards are fixed by means of a bonding medium layer. The conductive connector 50 may be connected in an up-and-down manner, or may be an implementation of the conductive connector shown in any one of the foregoing embodiments, and is not limited thereto.

In the embodiment as shown in FIG. 10B, the fourth prefabricated board B4 may also be provided with a magnetic assembly, and the fourth prefabricated board B4 may have the same structure as the second prefabricated board B2, or may adopt the structure of other embodiments disclosed in the present disclosure. In the present embodiment, the fourth prefabricated board B4 and the second prefabricated board B2 have the same structure as an example for description. The upper surface and the lower surface of the fourth prefabricated board B4 are respectively recessed in the horizontal winding direction to form an accommodating space 61a and 61b, and after the fourth prefabricated board B4 and the second prefabricated board B2 are laminated, the accommodating spaces 61b and 60a are in communication. The horizontal wiring layers 51 on the second prefabricated board and the fourth prefabricated board are electrically connected by means of the conductive connectors 50. Similarly, the exhaust channel may also be disposed on a side surface of the prefabricated board. By adding the fourth prefabricated board, more accommodating spaces and component setting surfaces are formed, so that not only the stacking of the magnetic assemblies in the vertical direction is realized, more elements can be assembled together in the vertical direction, the area of the substrate in the horizontal direction is reduced, and the integrated level of the substrate is further improved.

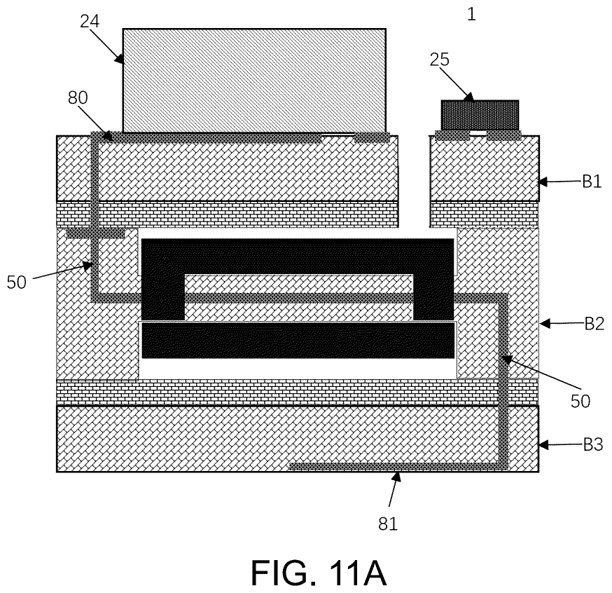

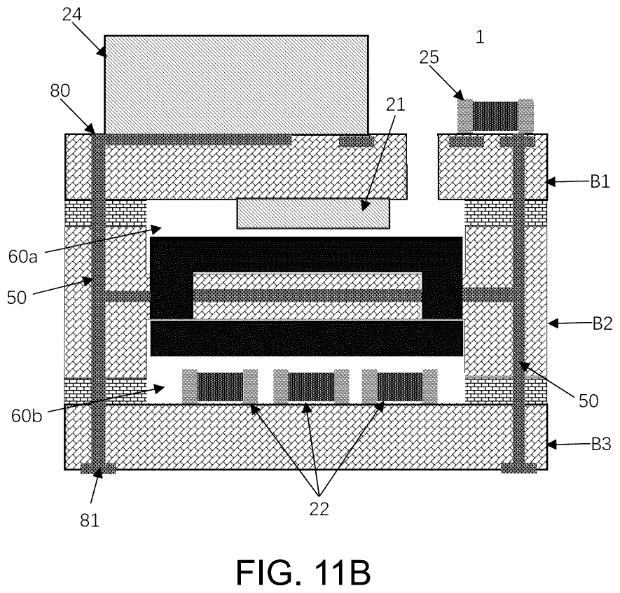

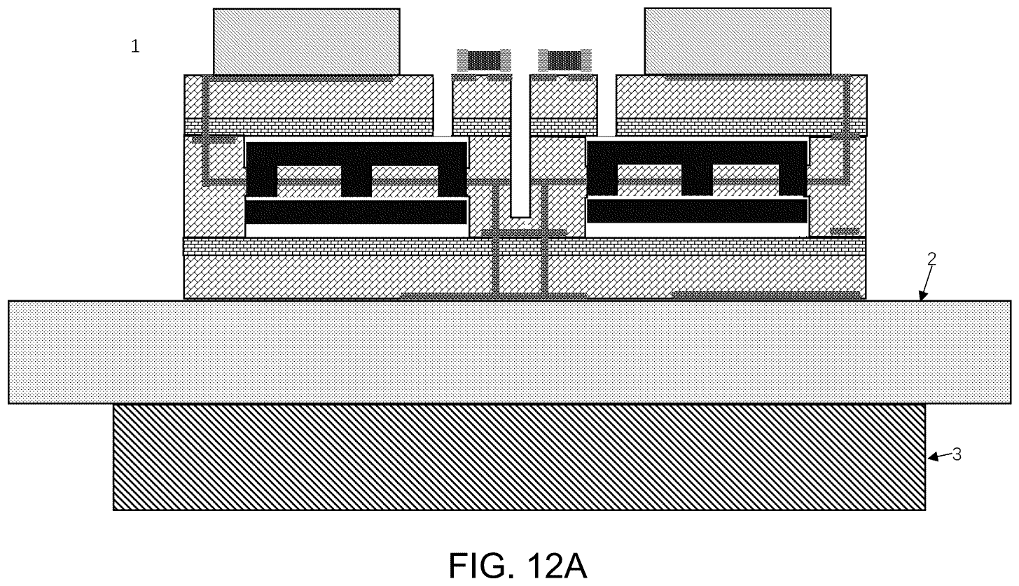

The structure of the substrate disclosed in the present invention can be applied to a power conversion device. Details are shown in FIGS. 11A-11C. FIG. 11A and FIG. 11B show a DC/DC voltage conversion module structure, which can directly arrange a power semiconductor and a passive element on an upper surface of a first prefabricated board B1, and is electrically connected to an inner wiring layer and/or a horizontal wiring layer 51 by means of a conductive connector. The lower surface of the third prefabricated board B3 is provided with a pad, on the one hand, the pad is connected to the conductive connector or the wiring layer in the prefabricated board, on the other hand, the pad is served as the external pad of the module 1 for being fixed and electrically connected to the external component.

The power module 1 shown in FIG. 11B has the same structure as shown in FIG. 11A, and only an element 21 is added within the accommodating space 60a. An element 22 is added in the accommodating space 60b. The element 21 may be a driving chip for driving the power semiconductor 24 nearby, so that the driving circuit can be effectively shortened; and the element 22 may be an output capacitor Co in the module 1 while being used as a filter capacitor of the load.

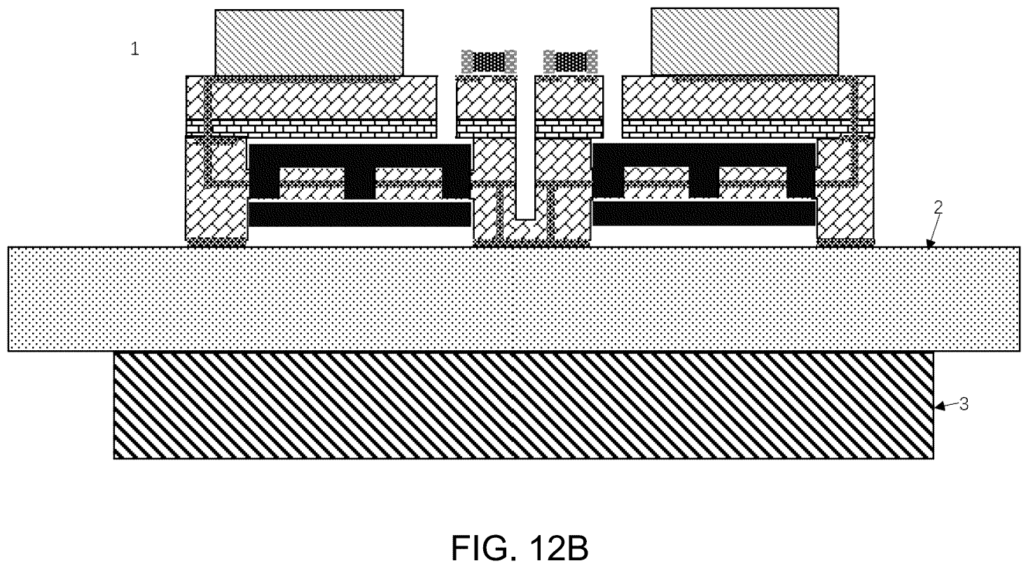

FIG. 12A illustrates an application of a unit array substrate. A module 1 of the application unit array substrate is disposed on an upper surface of the system main board 2. An integrated chip 3 is disposed on a lower surface of the system main board 2. The integrated chip 3 may be a CPU/GPU or the like. On the substrate, a semi-cutting groove is provided between adjacent units to release the stress of the substrate body, and at the same time, to reduce the rigidity of the substrate, thereby avoiding the influence on the system board 2 and the integrated chip 3. For example, when the substrate is rigid, the integrated chip 3 will be warped; and when the load amount of the integrated chip 3 is different, the temperature rise caused by the heat generated by the integrated chip 3 changes accordingly, and the temperature change causes a change in the warpage amount, and therefore, the heat conduction interface material is extruded, resulting in deterioration of the heat dissipation performance. Therefore, the use of the semi-cutting mode between the units can effectively avoid such adverse effects.

In the embodiments shown in FIG. 1 to FIG. 11, the third prefabricated board B3 may be removed, and the related steps of the third prefabricated board B3 in the manufacturing process of the first prefabricated board B1 and the second prefabricated board B2 can all be removed on the basis of the manufacturing process described in the foregoing embodiments. The accommodating space 60a may be recessed in the upper surface of the second prefabricated board B2, or may be recessed from the lower surface of the first prefabricated board B1. The accommodating space 60b is recessed from the lower surface of the second prefabricated board B2. In addition, as shown in FIG. 12B, a corresponding pad is provided on the lower surface of the second prefabricated board B2, and the second prefabricated board B2 is fixed and electrically connected to the system main board 2 through the pads. Furthermore, there is a gap between the lower magnetic cover and the upper surface of the system main board 2, and the gaps can be used for accommodating the element 22, more elements 22 can be arranged in a limited space, and the size of the power module is further reduced. The embodiment of the power module 1 shown in FIG. 12B is only an example. After the third prefabricated board is removed in the foregoing embodiment, as shown in FIG. 12B, the same technical effect can also be obtained.

The technical features disclosed in the present invention can be cross-applied according to actual requirements, and are not disclosed by the embodiments.

The power module according to the above embodiments may also be a part of the electronic device, which may satisfy the technical features and benefits disclosed in the present disclosure.

The “equal” or “same” or “equal to” disclosed by the application needs to consider the parameter distribution of engineering, and the error distribution is within +/−30%; and the included angle between the two line segments or the two straight lines is less than or equal to 45 degrees; the included angle between the two line segments or the two straight lines is within the range of [60, 120]; and the definition of the phase error phase also needs to consider the parameter distribution of the engineering, and the error distribution of the phase error degree is within +/−30%.

The embodiments in the specification are described in a progressive manner, each embodiment focuses on the difference from other embodiments, and the same similar parts between the embodiments can be referred to each other.

The above description of the disclosed embodiments enables a person skilled in the art to implement or use the present application. Various modifications to these embodiments will be readily apparent to those skilled in the art, and the generic principles defined herein may be implemented in other embodiments without departing from the spirit or scope of the application. Thus, the present application will not be limited to the embodiments shown herein but is to be accorded the widest scope consistent with the principles and novel features disclosed herein.

What is claimed is:

1. A high-integrated substrate, comprising a first prefabricated board, a second prefabricated board, a third prefabricated board, a first accommodating space and a second accommodating space, wherein the first prefabricated board, the second prefabricated board and the third prefabricated board are stacked in sequence; the first accommodating space is arranged between the first prefabricated board and the second prefabricated board, and the second accommodating space is arranged between the second prefabricated board and the third prefabricated board;
the second prefabricated board further comprises at least two opening windows, and the opening windows penetrate the upper surface and the lower surface of the second prefabricated board;
the high-integrated substrate further comprises a magnetic assembly, at least two conductive connectors, a bonding medium, and an exhaust channel;
the magnetic assembly comprises a winding and a magnetic core assembly; the winding is disposed in or on a surface of a second prefabricated board and is disposed adjacent to the opening window; the magnetic core assembly comprises an upper magnetic cover, a lower magnetic cover and a magnetic column, wherein each magnetic column passes through one of the opening window, and the upper magnetic cover and the lower magnetic cover respectively assembled with the board from the upper surface and the lower surface of the second prefabricated board; the upper magnetic cover is accommodated in the first accommodating space, and the lower magnetic cover is accommodated in the second accommodating space;
the first prefabricated board and the second prefabricated board, as well as the second prefabricated board and the third prefabricated board, are bonded and fixed by means of a bonding medium;
the at least two conductive connectors are electrically connected to two ends of the winding respectively, one of the conductive connectors is electrically connected to the first prefabricated board, and the other of the conductive connectors is electrically connected to the third prefabricated board;
the exhaust channel realizes communication between the first accommodating space and/or the second accommodating space and the outside.

2. The high-integrated substrate of claim 1, wherein a length L of the winding is greater than a thickness H of the upper magnetic cover.

3. The high-integrated substrate of claim 1, wherein a gap exists between an outer surface of the magnetic core assembly and an inner wall of the first accommodating space and an inner wall of the second accommodating space.

4. The high-integrated substrate of claim 1, wherein the exhaust channel penetrates through the upper surface and the lower surface of the first prefabricated board; or the exhaust channel is disposed on a sidewall of the first prefabricated board, the second prefabricated board, or the third prefabricated board.

5. The high-integrated substrate of claim 1, wherein the first accommodating space is formed by recessing a lower surface of the first prefabricated board, or is formed by recessing an upper surface of the second prefabricated board; and the second accommodating space is formed by recessing a lower surface of the second prefabricated board, or is formed by recessing an upper surface of the third prefabricated board.

6. The high-integrated substrate of claim 5, further comprising an element disposed on a lower surface of the first prefabricated board and/or an upper surface of the third prefabricated board.

7. The high-integrated substrate of claim 6, wherein an element provided on the upper surface of the third prefabricated board comprises a capacitor; the third prefabricated board further comprises a surface wiring layer on the upper surface, a surface wiring layer on the lower surface, a first wiring layer and a second wiring layer adjacent to the first wiring layer; the surface wiring layer on the upper surface and the surface wiring layer on the lower surface both comprise a positive end pad and a negative end pad, the first wiring layer and the second wiring layer both comprise a copper spreading layer, the positive end pad of the upper surface, the copper spreading layer of the first wiring layer, and the positive end pad of the lower surface are electrically connected by means of a via hole; the negative end pad of the upper surface, the copper spreading layer of the second wiring layer, and the negative end pad of the lower surface are electrically connected by means of a via hole; the copper spreading layer of the first wiring layer and the copper spreading layer of the second wiring layer overlap each other; the positive end pad is electrically connected to the positive end of the capacitor, and the negative end pad is electrically connected to the negative end of the capacitor.

8. The high-integrated substrate of claim 1, wherein the high-integrated substrate forms a plate edge metal by means of a plate edge metallization process, and the plate edge metal is connected to a surface wiring layer on the upper surface and/or a surface wiring layer on the lower surface of the high-integrated substrate.

9. The high-integrated substrate board of claim 8, wherein the plate edge metal is electrically connected to the conductive connector and the winding.

10. The high-integrated substrate of claim 8, wherein the plate edge metallization process comprises:
plating metal on the high-integrated substrate, and providing a tin-plated layer on the metal;
at part of the position on the side wall of the high-integrated substrate, the tin-plated layer is removed by mechanical, laser, etc. and then the exposed excess metal is etched away.

11. The high-integrated substrate of claim 1, wherein the winding comprises embedded thick copper embedded in the second prefabricated board, and any one of the upper surface, the lower surface or the side wall of the thick copper is exposed on the surface of the second prefabricated board.

12. The high-integrated substrate of claim 1, wherein the windings are a plurality of windings connected in parallel.

13. The high-integrated substrate of claim 1, wherein the winding is a special-shaped copper material, the special-shaped copper material comprises a horizontal portion and two vertical portions, and end surfaces of the two vertical portions are respectively exposed on an upper surface and a lower surface of the second prefabricated board.

14. The high-integrated substrate board of claim 1, wherein the conductive connector is formed gradually added step-by-step through a blind groove plating process.

15. The high-integrated substrate of claim 1, wherein the conductive connector comprises a copper block, a via hole, and a conductive bonding material; the copper block is disposed in the third prefabricated board, the via hole is disposed in the second prefabricated board, and the via hole and the copper block are connected by a conductive bonding material.

16. The high-integrated substrate of claim 1, further comprising an outer wiring layer, wherein the outer wiring layer is provided on an upper surface of the first prefabricated board or a lower surface of the third prefabricated board; the outer wiring layer comprises at least one wiring layer, and the at least one wiring layer is electrically connected to the prefabricated board by means of a blind hole or a through hole.

17. The high-integrated substrate of claim 1, further comprising a fourth prefabricated board, wherein the fourth prefabricated board is arranged between the first prefabricated board and the second prefabricated board or between the second prefabricated board and the third prefabricated board, and the fourth prefabricated board is bonded to the first prefabricated board and the second prefabricated board or the second prefabricated board and the third prefabricated board by means of a bonding medium, respectively; further comprising a third accommodating space, wherein the third accommodating space is disposed between the first prefabricated board and the fourth prefabricated board or between the third prefabricated board and the fourth prefabricated board, and at least one element is disposed in the third accommodating space.

18. The high-integrated substrate of claim 17, wherein the fourth prefabricated board is provided with an exhaust channel.

19. The high-integrated substrate of claim 1, comprising a fourth prefabricated board, wherein the fourth prefabricated board is arranged between the first prefabricated board and the second prefabricated board, and the fourth prefabricated board is bonded to the first prefabricated board and the second prefabricated board respectively by means of a bonding medium; further comprising a third accommodating space, a fourth accommodating space, and another magnetic assembly; the third accommodating space is disposed between the first prefabricated board and the fourth prefabricated board, and the fourth accommodating space is disposed between the fourth prefabricated board and the second prefabricated board; the another magnetic assembly includes a winding, an upper magnetic cover, a lower magnetic cover, and at least two magnetic columns; the winding is disposed in the fourth prefabricated board, the fourth prefabricated board further includes at least two opening windows for the magnetic columns of the another magnetic assembly to pass through, the upper magnetic cover of the another magnetic assembly is disposed in the third accommodating space, and the lower magnetic cover of the another magnetic assembly is disposed in the fourth accommodating space.

20. The high-integrated substrate of claim 1, wherein the number of the magnetic assembly is at least two, each of the magnetic assemblies is correspondingly provided with an independent first accommodating space and an independent second accommodating space, each of the magnetic assemblies is correspondingly provided with an independent winding, and the windings of the magnetic assemblies are not electrically connected.

21. The high-integrated substrate of claim 1, wherein the number of the magnetic assembly is at least two, each of the magnetic assemblies is correspondingly provided with an independent first accommodating space and an independent second accommodating space, each of the magnetic assemblies is correspondingly provided with an independent winding, the same polarity of the windings of the magnetic assemblies are electrically connected to each other, and are electrically connected to the conductive connectors.

22. The high-integrated substrate of claim 1, wherein there are at least two magnetic assemblies, each of the magnetic assemblies is correspondingly provided with an independent first accommodating space and an independent second accommodating space, each magnetic assembly is correspondingly provided with an independent winding, and a semi-cutting groove is provided between two adjacent magnetic assemblies.

23. The high-integrated substrate of claim 1, wherein the number of the opening window is four, the magnetic assembly comprises four magnetic columns and four windings, each of the windings is arranged around one magnetic column, and the length L of the winding is greater than the thickness H of the upper magnetic cover.

24. A power module, comprising a high-integrated substrate of claim 1, and further comprising a power semiconductor and a capacitor, wherein the power semiconductor and the capacitor are arranged on an upper surface of the high-integrated substrate, and the power semiconductor is electrically connected to the winding by means of a pad and a conductive connector provided on an upper surface of the high-integrated substrate.

25. The power module of claim 24, wherein the lower surface of the third prefabricated board is provided with a pad; the capacitor is electrically connected to the pad of the lower surface of the third prefabricated board by means of the conductive connector; and the power semiconductor is electrically connected to the pad of the lower surface of the third prefabricated board by means of the conductive connector.

26. The power module of claim 25, further comprising a driver chip disposed on a lower surface of the first prefabricated board.

27. The power module of claim 25, further comprising an output capacitor disposed on an upper surface of the third prefabricated board.

28. The power module of claim 24, wherein the power module is configured to supply power vertically, and is disposed on a surface of the main board of the system and supplies power to an integrated circuit disposed on the other side of the main board of the system.

29. The manufacturing method of the high-integrated substrate of claim 1, comprising the following steps:
step 1, fabricating a first prefabricated board, a second prefabricated board and a third prefabricated board, processing a first accommodating space on the lower surface of the first prefabricated board or the upper surface of the second prefabricated board, processing a second accommodating space on the lower surface of the second prefabricated board or the upper surface of the third prefabricated board, and processing at least two opening windows in communication with the first accommodating space and the second accommodating space on the second prefabricated board;
step 2, assembling a magnetic core on the second prefabricated board;
step 3, laminating the first prefabricated board and the third prefabricated board by means of a bonding medium stack on an upper surface and a lower surface of the second prefabricated board to form a laminate;
step 4, vertically punching a via hole on the laminate, electroplating a sidewall of the via hole, and electrically connecting a corresponding wiring layer;
step 5, drilling a hole in an upper wall of the first prefabricated board and/or in a side wall of the first prefabricated board or the second prefabricated board to the first accommodating space to form an exhaust channel.

30. The manufacturing method of the high-integrated substrate of claim 6, comprising the following steps:
step 1, prefabricated first prefabricated board, second prefabricated board, and third prefabricated board, the first accommodating space and the second accommodating space being respectively processed on the upper surface and the lower surface of the second prefabricated board, and at least two opening windows in communication with the first accommodating space and the second accommodating space are processed on the second prefabricated board; and an element is provided on the lower surface of the first prefabricated board, a magnetic core is assembled on the second prefabricated board, and an element is provided on the upper surface of the third prefabricated board;
Step 2: disposing a bonding medium on an upper surface and a lower surface of the second prefabricated board, and partially curing;
Step 3, removing a bonding medium at a position corresponding to the upper magnetic cover and the lower magnetic cover of the magnetic core; laminating the first prefabricated board, the second prefabricated board, and the third prefabricated board;
Step 4, vertically punching a via hole on the laminate, electroplating a sidewall of the via hole, and electrically connecting a corresponding wiring layer;
Step 5: drilling the first prefabricated board to a first accommodating space to form an exhaust channel.
